(19) United States
(12) Patent Application Publication
(10) Pub. No.: US 2026/0213732 A1
(43) Pub. Date: Jul. 23, 2026

(54) INTERDIGITAL TRANSDUCER CAPACITOR WITH SUPPORT PILLAR

(71) Applicant: Skyworks Solutions, Inc., Irvine, CA (US)

(72) Inventors: Rei Goto, Osaka-Shi (JP); Shoji Okamoto, Hirakata-Shi (JP)

(21) Appl. No.: 19/435,371

(22) Filed: Dec. 29, 2025

Related U.S. Application Data
(60) Provisional application No. 63/748,041, filed on Jan. 22, 2025.
(60) Provisional application No. 63/748,060, filed on Jan. 22, 2025.

(51) Int. Cl. H03H 9/64; H03H 9/145; H03H 9/25

(52) U.S. Cl. CPC H03H 9/6479; H03H 9/145; H03H 9/25

(57) ABSTRACT

A packaged acoustic wave device is disclosed. Ther packaged acoustic wave device can include an interdigital transducer capacitor, a support pillar over the interdigital transducer capacitor, and a packaging roof structure coupled to the support pillar. The support pillar can include an insulating material. The packaged acoustic wave device can include a signal line over the insulating material. The signal line can be electrically coupled to a signal terminal of an acoustic wave device. The support pillar or insulating material can increase capacitance while reducing lateral dimensions of the packaged acoustic wave device.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/748,041, filed on Jan. 22, 2025, titled “INTERDIGITAL TRANSDUCER CAPACITOR WITH SUPPORT PILLAR,” and U.S. Provisional Patent Application No. 63/748,060, filed on Jan. 22, 2025, titled “INTERDIGITAL TRANSDUCER CAPACITOR WITH SIGNAL LINE SPACED BY INSULATOR” are hereby incorporated by reference under 37 CFR 1.57 in their entirety herein.

### BACKGROUND

### Field

Embodiments of this disclosure relate to interdigital transducer (IDT) capacitors.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A SAW resonator can include an interdigital transducer electrode on a piezoelectric substrate. The surface acoustic wave resonator can generate a surface acoustic wave on a surface of the piezoelectric layer on which the interdigital transducer electrode is disposed. A multilayer piezoelectric substrate surface acoustic wave (MPS-SAW) resonator is an example of the SAW resonator. Capacitors can be provided with the filter to provide additional capacitance for one or more resonators of the filter.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a packaged acoustic wave device including: an interdigital transducer capacitor; a support pillar over the interdigital transducer capacitor, the support pillar including an insulating material; and a packaging roof structure coupled to the support pillar.

In some embodiments, the techniques described herein relate to a packaged acoustic wave device wherein the insulating material of the support pillar includes a polyimide.

In some embodiments, the techniques described herein relate to a packaged acoustic wave device wherein the insulating material of the support pillar includes an epoxy-based resin.

In some embodiments, the techniques described herein relate to a packaged acoustic wave device wherein the packaging roof structure includes a dielectric plate.

In some embodiments, the techniques described herein relate to a packaged acoustic wave device wherein the packaging roof structure further includes a conductive layer over the dielectric plate.

In some embodiments, the techniques described herein relate to a packaged acoustic wave device further including a seal ring, wherein the packaging roof structure is coupled to the seal ring.

In some embodiments, the techniques described herein relate to a packaged acoustic wave device wherein the seal ring and the packaging roof structure together seal a cavity in which the interdigital transducer capacitor is provided.

In some embodiments, the techniques described herein relate to a packaged acoustic wave device wherein the seal ring surrounds the cavity and the cavity is hermetically sealed.

In some embodiments, the techniques described herein relate to a packaged acoustic wave device wherein the interdigital transducer capacitor includes a piezoelectric layer and an interdigital transducer electrode positioned between at least a portion of the piezoelectric layer and the support pillar.

In some embodiments, the techniques described herein relate to a packaged acoustic wave device wherein the interdigital transducer capacitor further includes a support structure including a support substrate, the piezoelectric layer is positioned over the support structure.

In some embodiments, the techniques described herein relate to a packaged acoustic wave device wherein the support structure further includes an intermediate structure between the support substrate and the piezoelectric layer.

In some embodiments, the techniques described herein relate to a packaged acoustic wave device wherein the intermediate structure includes a functional layer and a trap-rich layer.

In some aspects, the techniques described herein relate to a packaged filter including: a multi-layer piezoelectric substrate including a support substrate and a piezoelectric layer over the support substrate, the multi-layer piezoelectric substrate having a first region and a second region; an interdigital transducer capacitor in the first region; an acoustic wave device in the second region; a support pillar over the interdigital transducer capacitor, the support pillar including an insulating material; and a packaging roof structure coupled to the multi-layer piezoelectric substrate via a seal ring and the support pillar.

In some embodiments, the techniques described herein relate to a packaged filter wherein the insulating material of the support pillar includes a polyimide or an epoxy-based resin.

In some embodiments, the techniques described herein relate to a packaged filter wherein the packaging roof structure includes a dielectric plate.

In some embodiments, the techniques described herein relate to a packaged filter wherein multi-layer piezoelectric substrate further includes an intermediate structure between the support substrate and the piezoelectric layer.

In some aspects, the techniques described herein relate to a packaged interdigital transducer capacitor including: a piezoelectric layer; a support pillar including an insulating material; an interdigital transducer electrode between the piezoelectric layer and the support pillar; and a packaging roof structure coupled to the support pillar.

In some embodiments, the techniques described herein relate to a packaged interdigital transducer capacitor wherein the insulating material of the support pillar includes a polyimide or an epoxy-based resin.

In some embodiments, the techniques described herein relate to a packaged interdigital transducer capacitor further including a support structure including a support substrate, the piezoelectric layer is positioned over the support structure.

In some embodiments, the techniques described herein relate to a packaged interdigital transducer capacitor wherein the support structure further includes an intermediate structure between the support substrate and the piezoelectric layer, the intermediate structure includes a functional layer and a trap-rich layer.

In some aspects, the techniques described herein relate to a packaged acoustic wave device including: an interdigital transducer capacitor; an insulator over the interdigital transducer capacitor; and a signal line over the insulator.

In some embodiments, the techniques described herein relate to a packaged acoustic wave device wherein the signal line includes a conductive plate.

In some embodiments, the techniques described herein relate to a packaged acoustic wave device wherein the insulator includes a polyimide.

In some embodiments, the techniques described herein relate to a packaged acoustic wave device wherein the insulator includes an epoxy-based resin.

In some embodiments, the techniques described herein relate to a packaged acoustic wave device further including an acoustic wave device, wherein the signal line is coupled to a signal terminal of the acoustic wave device.

In some embodiments, the techniques described herein relate to a packaged acoustic wave device wherein the signal line extends across a first end of the interdigital transducer capacitor and a second end of the interdigital transducer capacitor opposite the first end.

In some embodiments, the techniques described herein relate to a packaged acoustic wave device further including a seal ring and a packaging roof structure coupled to the seal ring.

In some embodiments, the techniques described herein relate to a packaged acoustic wave device wherein the seal ring and the packaging roof structure together seal a cavity in which the interdigital transducer capacitor is provided.

In some embodiments, the techniques described herein relate to a packaged acoustic wave device wherein the seal ring surrounds the cavity and the cavity is hermetically sealed.

In some embodiments, the techniques described herein relate to a packaged acoustic wave device wherein the packaging roof structure is spaced from the signal line by a gap.

In some embodiments, the techniques described herein relate to a packaged acoustic wave device wherein the packaging roof structure is spaced from the signal line by an insulating spacer.

In some embodiments, the techniques described herein relate to a packaged acoustic wave device wherein the interdigital transducer capacitor includes a piezoelectric layer and an interdigital transducer electrode positioned between at least a portion of the piezoelectric layer and the insulator.

In some embodiments, the techniques described herein relate to a packaged acoustic wave device wherein the interdigital transducer capacitor further includes a support structure including a support substrate, the piezoelectric layer is positioned over the support structure.

In some embodiments, the techniques described herein relate to a packaged acoustic wave device wherein the support structure further includes an intermediate structure between the support substrate and the piezoelectric layer.

In some embodiments, the techniques described herein relate to a packaged acoustic wave device wherein the intermediate structure includes a functional layer and a trap-rich layer.

In some aspects, the techniques described herein relate to a packaged filter having a first region and a second region, the packaged filter including: an interdigital transducer capacitor in the first region; an acoustic wave device in the second region; an insulator over the interdigital transducer capacitor; and a signal line over the insulator, the signal line coupled to a signal terminal of the acoustic wave device.

In some embodiments, the techniques described herein relate to a packaged filter wherein the signal line includes a conductive plate that extends across a first end of the interdigital transducer capacitor and a second end of the interdigital transducer capacitor opposite the first end.

In some embodiments, the techniques described herein relate to a packaged filter wherein the insulator includes a polyimide or an epoxy-based resin.

In some embodiments, the techniques described herein relate to a packaged interdigital transducer capacitor including: a piezoelectric layer; an insulator; an interdigital transducer electrode between the piezoelectric layer and the insulator; and a signal line over the insulator.

In some embodiments, the techniques described herein relate to a packaged interdigital transducer capacitor further including a support structure including a support substrate, the piezoelectric layer is positioned over the support structure, wherein the insulator includes a polyimide or an epoxy-based resin.

### BRIEF DESCRIPTION OF THE DRAWINGS

Embodiments of this disclosure will now be described, by way of non-limiting example, with reference to the accompanying drawings.

FIG. 1A is a schematic cross-sectional side view of an IDT capacitor according to an embodiment.

FIG. 1B is a top-plan view of the IDT capacitor of FIG. 1A.

FIG. 1C is a schematic top plan view of the packaged acoustic wave device that includes the IDT capacitor of FIGS. 1A and 1B and one or more acoustic wave devices.

FIG. 2A is a schematic cross-sectional side view of an IDT capacitor according to an embodiment.

FIG. 2B is a top-plan view of the IDT capacitor of FIG. 2A.

FIG. 3A is a schematic cross-sectional side view of the IDT capacitor of FIGS. 2A and 2B with a signal line that electrically couples a terminal of an acoustic wave device to another terminal.

FIG. 3B is a schematic top plan view of FIG. 3A.

FIG. 3C is a schematic cross-sectional side view of an IDT capacitor according to an embodiment.

FIG. 4A is a schematic diagram of an example multiplexer that includes surface acoustic wave devices according to an embodiment.

FIG. 4B is a schematic diagram of another multiplexer that includes surface acoustic wave devices according to an embodiment.

FIG. 5 is a schematic diagram of a radio frequency module that includes a surface acoustic wave component.

FIG. 6 is a schematic diagram of a radio frequency module that includes a surface acoustic wave resonator according to an embodiment.

FIG. 7 is a schematic block diagram of a module that includes duplexers and an antenna switch.

FIG. 8A is a schematic block diagram of a module that includes a power amplifier, a radio frequency switch, and duplexers, in accordance with one or more embodiments.

FIG. 8B is a schematic block diagram of a module that includes filters, a radio frequency switch, and a low noise amplifier, according to an embodiment.

FIG. 9A is a schematic diagram of a wireless communication device that includes filters in a radio frequency front end, according to an embodiment.

FIG. 9B is a schematic diagram of a wireless communication device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate surface acoustic wave (MPS-SAW) device.

A capacitor can provide additional capacitance in parallel or in series with a SAW resonator of a filter. Capacitors can be used for various purposes in filters and/or other electronic circuits, such as tuning the resonant frequency or providing impedance matching. The capacitors can be coupled with SAW resonators to achieve desired electrical characteristics. For example, a capacitor in parallel with a SAW resonator of a filter can shift (increase or decrease) the coupling factor (kt²) and improve the skirt performance and the insertion loss of the filter. In some applications, such a capacitor is provided separately from the SAW resonator. The separately provided capacitor can introduce, for example, losses in the filter.

An interdigital transducer capacitor can enable integration of the capacitor with a resonator on a common piezoelectric layer. Such integration can lower losses in the filter. In an IDT capacitor, a larger static capacitance can be beneficial for enhancing signal strength by allowing a greater charge storage capacity, which improves the coupling of the transducer to the acoustic wave medium. However, it can be challenging to provide the interdigital transducer (IDT) capacitor that has a relatively large capacitance without increasing the capacitor size. This is true especially for an MPS-IDT capacitor.

An acoustic wave device, such as an acoustic wave filter, that includes at least one IDT capacitor and at least one acoustic wave device (e.g., a SAW resonator) can be packaged as a packaged acoustic wave device. The acoustic wave device can be packaged using a packaging roof structure or a packaging cap structure, and a sealing structure (e.g., a seal ring). One or more support pillars that support the roof structure can be included for maintaining structural integrity, especially when the lateral dimension of the acoustic wave device is relatively large. The one or more support pillars are provided laterally between the at least one IDT capacitor and the at least one acoustic wave device. Therefore, when the support pillars are implemented the lateral size of the acoustic wave device increases. Also, the acoustic wave device includes one or more signal lines that are connected to the signal terminal(s) of the least one acoustic wave device. The signal lines are provided laterally between the at least one IDT capacitor and the at least one acoustic wave device. Therefore, the signal lines can increase the lateral size of the acoustic wave device.

Embodiments disclosed herein relate to packaged acoustic wave devices having one or more IDT capacitors that provides improved capacitance while reducing lateral dimensions of the acoustic wave devices. According to an embodiment, a packaged acoustic wave device can include an interdigital transducer capacitor, a support pillar over the interdigital transducer capacitor, and a packaging roof structure coupled to the support pillar. The support pillar includes an insulating material. According to another embodiment, a packaged acoustic wave device can include an interdigital transducer capacitor, an insulator over the interdigital transducer capacitor, and a signal line over the insulator. The packaged acoustic wave device can include an acoustic wave device, such as a resonator (e.g., a SAW resonator) and the signal line can be electrically coupled to a signal terminal of the acoustic wave device.

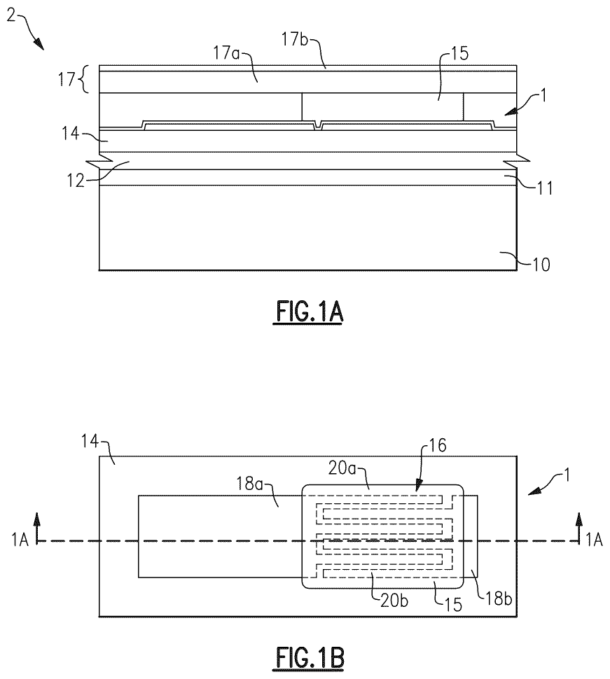

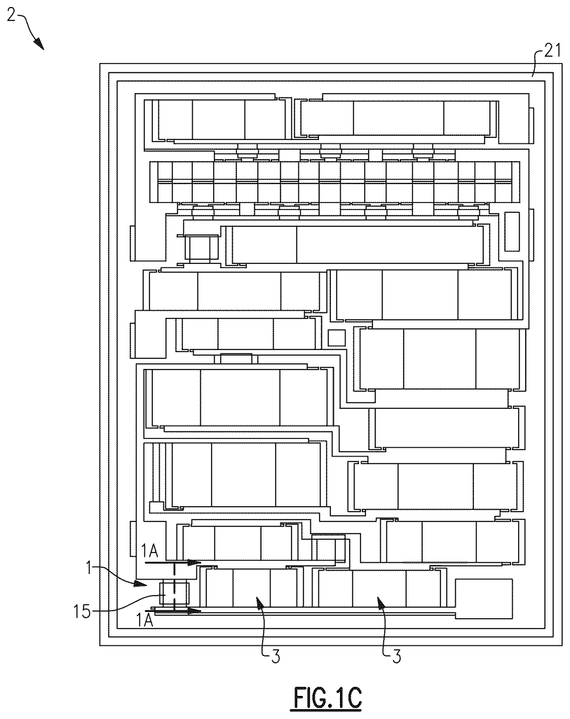

FIG. 1A is a schematic cross-sectional side view of an IDT capacitor 1 according to an embodiment. The IDT capacitor 1 shown in FIG. 1A can be a portion of a packaged acoustic wave device 2, such as an acoustic wave filter. FIG. 1B is a top-plan view of the IDT capacitor 1 of FIG. 1A. In FIG. 1B, certain components illustrated in FIG. 1A are omitted or made transparent to show internal components of the IDT capacitor 1. FIG. 1C is a schematic top plan view of the packaged acoustic wave device 2 that includes the IDT capacitor 1 and one or more acoustic wave devices 3. In FIG. 1C, certain components illustrated in FIG. 1A are omitted or made transparent to show internal components of the packaged acoustic wave device 2.

The packaged acoustic wave device 2 can include a support structure including a support substrate 10 and an intermediate structure that can include an intermediate layers 11, 12 over the support substrate 10, and a piezoelectric layer 14 over the intermediate layer 12 of the support structure. The support structure and the piezoelectric layer 14 can together define a multi-layer piezoelectric substrate. The packaged acoustic wave device 2 has a capacitor region corresponding to the IDT capacitor 1 and a resonator region corresponding to the one or more acoustic wave devices 3.

The IDT capacitor 1 can also include a cover layer (e.g., a support pillar 15) over the piezoelectric layer 14. The IDT capacitor 1 can include an IDT electrode between at least a portion of the piezoelectric layer 14 and the support pillar 15. The IDT electrode 16 can include a bus bar 18a, capacitor fingers 20a that extend from the bus bar 18a, a bus bar 18b, and capacitor fingers 20b that extend from the bus bar 18b.

The packaged acoustic wave device 2 can also include a roof structure 17 and a sealing structure (e.g., a seal ring 21). The roof structure 17 can be coupled to the multi-layer piezoelectric substrate via the seal ring 21. A cavity can be formed between the multi-layer piezoelectric substrate and the roof structure 17. The cavity can be hermetically sealed by the seal ring 21. In some embodiments, the seal ring 21 can surround (e.g., completely surround) the cavity. The roof structure 17 can also be coupled to the support pillar 15. The roof structure 17 can include any suitable material for packaging the components of the packaged acoustic wave device 2. In some embodiments, the roof structure 17 can include a dielectric plate 17a and a conductive layer 17b over the dielectric plate 17a. In some embodiments, the material of the roof structure 17 can enable thermal expansion matching between the multi-layer piezoelectric substrate and the roof structure 17. The support pillar 15 can provide additional structural support for the roof structure 17. Because the support pillar 15 is provided over the IDT capacitor 1, the support pillar 15 can be provided without increasing the lateral dimensions of the packaged acoustic wave device 2. Additional support pillars can be provided in any other suitable locations in the packaged acoustic wave device 2.

The support pillar 15 can include any suitable insulating material. The support pillar 15 can include a material that has a relatively large permittivity and/or a relatively high thermal conductivity. In some embodiments, the support pillar 15 can include a polyimide or an epoxy-based resin. For example, a polyimide can include aromatic polyimides, thermoset polyimides, polyetherimides (PEI), amorphous polyimides, siloxane-modified polyimides, fluorinated polyimides, bismaleimides (BMI), or soluble polyimides. For example, an epoxy-based resin can include bisphenol A epoxy resins, bisphenol F epoxy resins, cycloaliphatic epoxy resins, phenolic novolac epoxy resins, halogen-free epoxy resins, flame-retardant epoxy resins, thermally conductive epoxy resins, toughened epoxy resins, flexible epoxy resins, and waterborne epoxy resins. The support pillar 15 can increase the capacitance of the IDT capacitor 1 as compared to an IDT capacitor of the same size without support pillar 15.

The IDT electrodes (the IDT electrode 16 of the capacitor 1; and the IDT electrode of the acoustic wave device 3) can include any suitable IDT electrode material. For example, the electrodes can include molybdenum (Mo), aluminum (Al), copper (Cu), Magnesium (Mg), titanium (Ti), tungsten (W), the like, or any suitable combination thereof. The IDT electrodes can have a multilayer structure. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The interdigital transducer electrodes can be formed with (e.g., formed on or at least partially in) the piezoelectric layer 14. The piezoelectric layer 14 and the electrodes can be provided in any suitable manner. For example, the piezoelectric layer 14 and the electrodes can be provided in sequence. When the electrodes are provided at least partially in the piezoelectric layer 14, the piezoelectric layer 14 can be partially etched and/or provided in a plurality of steps.

The support substrate 10 can have a relatively high acoustic impedance. For example, the support substrate 10 can have a higher impedance than an impedance of the piezoelectric layer 14 and a higher thermal conductivity than a thermal conductivity of the piezoelectric layer 14. The support substrate 10 can be a silicon substrate, for example. The support substrate 10 can be formed of quartz, spinel, borosilicate, or the like. The support substrate 10 can include a dielectric material. For example, the support substrate 10 can include sapphire or aluminum oxide (Al₂O₃). As compared to some other materials, such as silicon, sapphire has lower or no parasitic surface conductance as sapphire is dielectric. The multilayer piezoelectric substrate (MPS) that includes a sapphire support substrate can be referred to as a sapphire MPS.

The intermediate layer 11 can be, for example, a trap-rich layer that can suppress the parasitic surface conductivity at a surface of the support substrate 10 while improving the quality factor (Q) as compared to a similar device without a trap-rich layer. In some embodiments, the intermediate layer 11 can be a polycrystalline silicon layer. In some embodiments, the intermediate layer 11 can be a doped region of the support substrate 10.

The intermediate layer 12 can be, for example, a single crystal layer. In some embodiments, the intermediate layer 12 can be a silicon oxide layer (e.g., a silicon dioxide (SiO₂) layer. In some embodiment, the intermediate layer 12 can function as an adhesion layer. In some embodiments, a thickness of the intermediate layer 12 can be the same as, generally similar to, or thinner than the thickness of the piezoelectric layer 14.

The piezoelectric layer 14 can include any suitable piezoelectric layer, such as a lithium based piezoelectric layer. Example lithium based piezoelectric materials include lithium tantalate and lithium niobate. In some embodiments, the piezoelectric layer 14 can be a lithium tantalate (LT) layer. For example, the piezoelectric layer 14 can be an LT layer having a cut angle of 20° (20°Y-cut X-propagation LT), a cut angle of 60° (60°Y-cut X-propagation LT), or a cut angle in a range from 20° to 60°. For example, the piezoelectric layer 14 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118°Y-cut X-propagation LN) or more or a cut angle of about 132° (132Y-cut X-propagation LN) or less. For example, the piezoelectric layer 14 can be 125±20° Y-cut LN, 125±15° Y-cut LN, 125±10° Y-cut LN, or 125±5° Y-cut LN. A thickness of the piezoelectric layer 14 can be selected based on a wavelength λ or L of a surface acoustic wave generated by the acoustic wave device 3 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5 L, 0.1 L to 0.3 L, or 0.1 L to 0.2 L. Selecting the thickness of the piezoelectric layer 14 from these ranges can be significant in avoiding significant frequency variation and providing sufficient temperature coefficient of frequency for the SAW device 2. In some embodiments, the piezoelectric layer 14 can include lithium tantalate (LT) and lithium niobate (LN).

The IDT capacitor 1 and the acoustic wave device 3 can be positioned in any suitable manner in the SAW device 2. In some embodiments, the capacitor 1 can be coupled in parallel with the acoustic wave device 3. The SAW device 2 can be implemented as part of a filter. The acoustic wave device 3 can be a series resonator or a shunt resonator in the filter.

The support pillar 15 illustrated in FIG. 1A provides support for the roof structure 17. In some other embodiments, the support pillar 15 can provide support for other parts other than the roof structure 17.

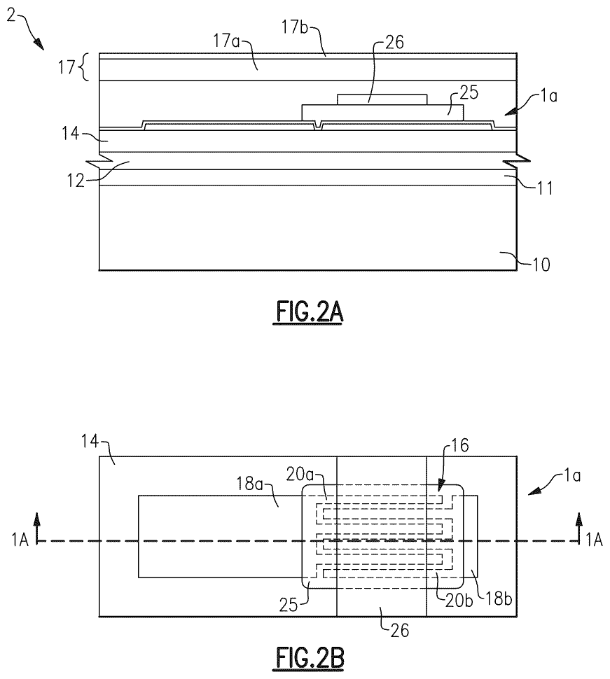

FIG. 2A is a schematic cross-sectional side view of an IDT capacitor 1a according to an embodiment. The IDT capacitor 1a shown in FIG. 2A can be a portion of the packaged acoustic wave device 2, such as an acoustic wave filter. FIG. 2B is a top-plan view of the IDT capacitor 1a of FIG. 2A. In FIG. 2B, certain components illustrated in FIG. 2A are omitted or made transparent to show internal components of the IDT capacitor 1a. Unless otherwise noted, the components shown in FIGS. 2A and 2B may be structurally and/or functionally the same as or generally similar to like components disclosed herein.

In the IDT capacitor 1a, instead of the support pillar 15, an insulator 25 is included. The material of the support pillar 15 and the material of the insulator 25 can be the same. Therefore, the support pillar 15 and the insulator 25 may be used interchangeably. The support pillar 15 and the insulator 25 are named and labeled differently for the purpose of describing the different embodiments.

As with the support pillar 15, the insulator 25 can include any suitable insulating material. In some embodiments, the insulator 25 can include a polyimide or an epoxy-based resin. For example, a polyimide can include aromatic polyimides, thermoset polyimides, polyetherimides (PEI), amorphous polyimides, siloxane-modified polyimides, fluorinated polyimides, bismaleimides (BMI), or soluble polyimides. For example, an epoxy-based resin can include bisphenol A epoxy resins, bisphenol F epoxy resins, cycloaliphatic epoxy resins, phenolic novolac epoxy resins, halogen-free epoxy resins, flame-retardant epoxy resins, thermally conductive epoxy resins, toughened epoxy resins, flexible epoxy resins, and waterborne epoxy resins. The insulator 25 can increase the capacitance of the IDT capacitor 1a as compared to an IDT capacitor of the same size without insulator 25.

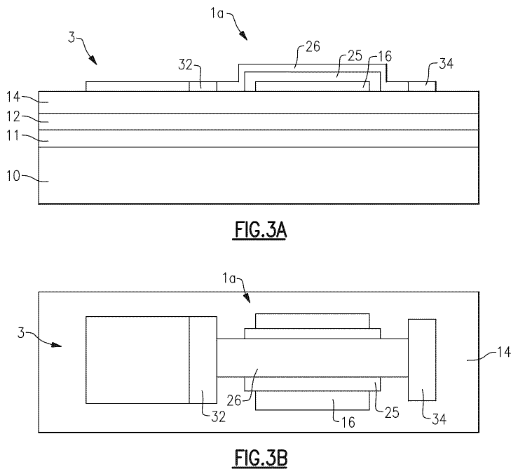

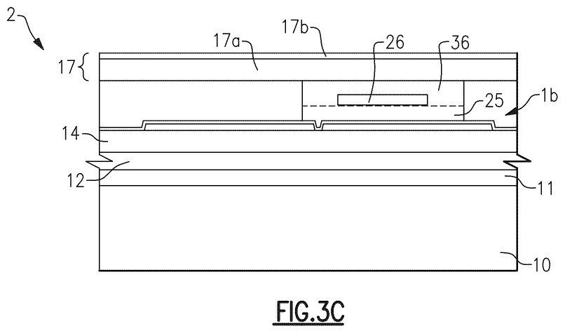

A routing structure (e.g., a signal line 26) can be provided over the insulator 25. In some embodiments, the routing structure can include a conductive plate. The insulator 25 can electrically insulate the signal line 26 from the IDT electrode 16 of the IDT capacitor 1a. The signal line 26 can be electrically coupled to a signal terminal of the acoustic wave device 3. An example connection between the IDT capacitor 1a and the acoustic wave device 3 is illustrated in FIGS. 3A and 3B. The signal line 26 can extend between a first end of the IDT capacitor 1a and a second end of the IDT capacitor 1a different from (e.g., opposite) the first end. By having the signal line 26 over the IDT capacitor 1a, instead of between the IDT capacitor 1a and the acoustic wave device 3, lateral dimensions of the packaged acoustic wave device 2 can be reduced.

In some embodiments, the signal line 26 can be spaced from the roof structure 17. There can be a gap between the signal line 26 and the roof structure 17. For example, the gap can be an airgap as shown in FIG. 2A. For another example, the gap can be filled with a spacer that includes an insulating material as shown in FIG. 3C.

FIG. 3A is a schematic cross-sectional side view of the IDT capacitor 1a of FIGS. 2A and 2B with a signal line 26 that electrically couples a terminal 32 of an acoustic wave device 3 to another terminal 34. FIG. 3B is a schematic top plan view of FIG. 3A. Unless otherwise noted, the components shown in FIGS. 3A and 3B may be structurally and/or functionally the same as or generally similar to like components disclosed herein. The IDT capacitor 1a and the acoustic wave device 3 can be implemented in the packaged acoustic wave device 2.

As shown in FIGS. 3A and 3B, the signal line 26 can electrically couple the terminal 32 of the acoustic wave device 3 to the terminal 34. The terminal 34 can be a terminal of another component in the packaged acoustic wave device 2 or a I/O terminal of the packaged acoustic wave device 2.

FIG. 3C is a schematic cross-sectional side view of an IDT capacitor 1b according to an embodiment. The IDT capacitor 1b shown in FIG. 3C can be a portion of the packaged acoustic wave device 2, such as an acoustic wave filter. Unless otherwise noted, the components shown in FIG. 3C may be structurally and/or functionally the same as or generally similar to like components disclosed herein.

The IDT capacitor 1b is generally similar to the IDT capacitor 1a, except that the IDT capacitor 1b also includes a spacer 36. The spacer 36 can include the same material as the insulator 25, in some embodiments. In some applications, the insulator 25 and the spacer 36 can together function as a support pillar for the roof structure 17.

The IDT capacitors disclosed herein can be implemented in a single packaged acoustic wave device, in some applications. For example, any suitable combinations of the IDT capacitors 1a, 1b can be implemented in the packaged acoustic wave device 2 along with one or more acoustic wave devices 3.

Any suitable combinations of two or more features disclosed herein can be made in various forms. An acoustic wave device (e.g., an IDT capacitor) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more IDT capacitors disclosed herein. FR1 can be from 410 MHz to 7.125 GHz, for example, as specified in a current 5G NR specification. One or more IDT capacitors in accordance with any suitable principles and advantages disclosed herein can be included in a filter arranged to filter a radio frequency signal in a 4G LTE operating band and/or in a filter having a passband that includes a 4G LTE operating band and a 5G NR operating band.

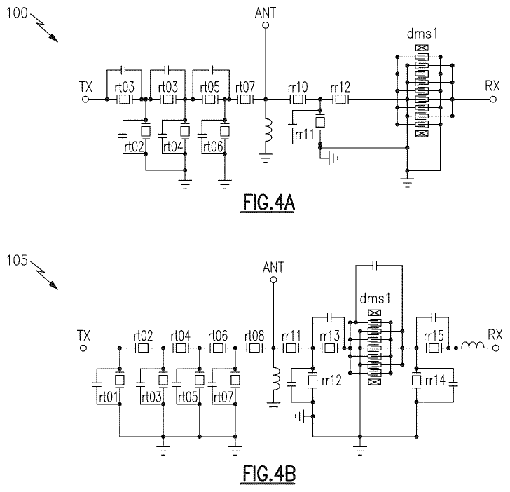

FIG. 4A is a schematic diagram of an example multiplexer 100 that includes surface acoustic wave devices according to an embodiment. The multiplexer 100 can be a duplexer. The multiplexer 100 includes a transmit filter and a receive filter. For example, the transmit filter can be a band pass filter. The illustrated transmit filter in the multiplexer 100 is arranged to filter a radio frequency signal received at a transmit port TX and provide a filtered output signal to an antenna port ANT. The illustrated receive filter in the multiplexer 100 is arranged to filter a radio frequency signal received at the antenna port ANT and provide a filtered output to a receive port RX. The transmit filter includes resonators rt01 to rt07. The resonators rt01, rt03, rt05 are series resonators and rt02, rt04, tr06 are shunt resonators. The receive filter includes resonators rr10, rr11, rr12, and a multi-mode SAW filter (e.g., a double mode SAW filter dms1). The resonators rr10, rr12 are series resonators and the resonator rr1 is a shunt resonator.

The multiplexer 100 also includes capacitors coupled in parallel with the resonators rt01, rt02, rt03, rt04, rt05, rt06, rr11. The capacitors can include one or more IDT capacitors in accordance with any suitable principles and advantages disclosed herein. The transmit filter and the receive filter of the multiplexer 100 can have a relatively small gap between passbands. Using IDT capacitors disclosed herein can reduce the impact of one or more capacitors from the transmit filter on the passband of the receive filter and/or reduce the impact of one or more capacitors of the receive filter on the transmit filter. Also, the IDT capacitors disclosed herein can enable size reduction of the multiplexer 100.

FIG. 4B is a schematic diagram of another multiplexer 105 that includes surface acoustic wave devices according to an embodiment. The multiplexer 105 can be a duplexer. The multiplexer 105 includes a transmit filter and a receive filter. For example, the transmit filter can be a band pass filter. The illustrated transmit filter in the multiplexer 105 is arranged to filter a radio frequency signal received at a transmit port TX and provide a filtered output signal to an antenna port ANT. The illustrated receive filter in the multiplexer 105 is arranged to filter a radio frequency signal received at the antenna port ANT and provide a filtered output to a receive port RX. The transmit filter includes resonators rt01 to rt08. The resonators rt02, rt04, rt06, rt08 are series resonators and rt01, rt03, rt05, rt07 are shunt resonators. The receive filter includes resonators rr11 to rr15, and a multi-mode SAW filter (e.g., a double mode SAW filter dms1). The resonators rr1, rr13, rr15 are series resonators and the resonators rr12, rr14 are shunt resonators.

The multiplexer 105 also includes capacitors coupled in parallel with the resonators rt01, rt03, rt05, rt07, rt12, rt13, rr14, rr15 and with the DMS filter dms1. The capacitors can include one or more IDT capacitors in accordance with any suitable principles and advantages disclosed herein.

Any suitable filter topology can include an IDT capacitor in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

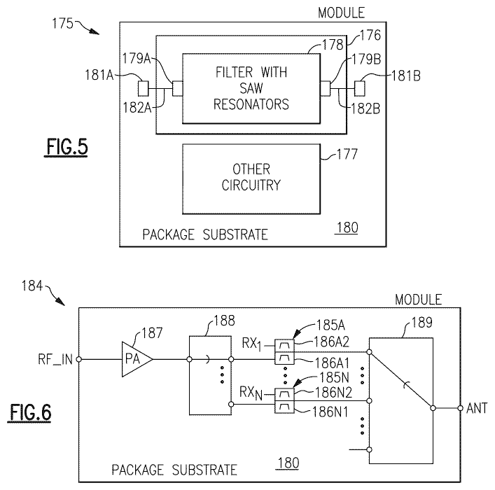

FIG. 5 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 5 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 5. The packaging substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 6 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate 180 can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 6 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

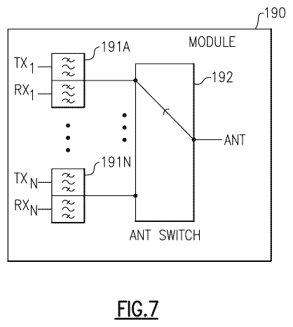

FIG. 7 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

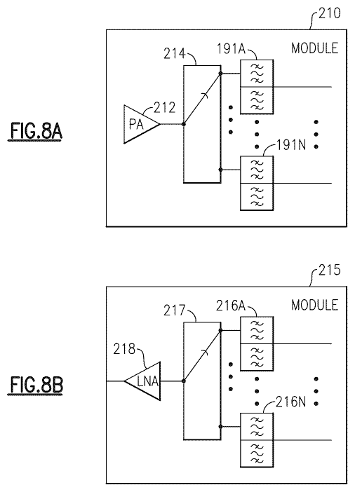

FIG. 8A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 8B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

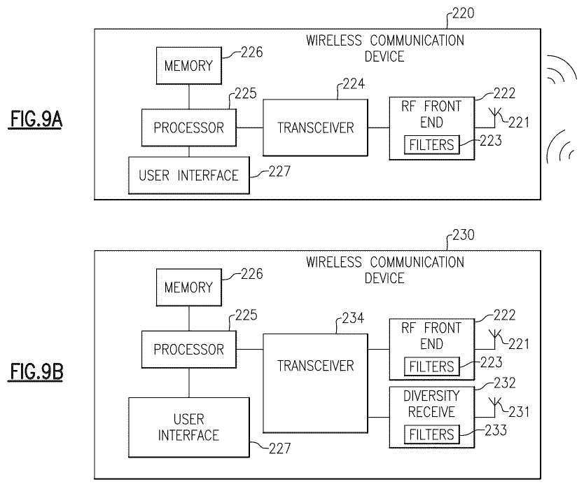

FIG. 9A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 9B is a schematic diagram of a wireless communication device 230 that includes filters 223 in a radio frequency front end 222 and a second filter 233 in a diversity receive module 232. The wireless communication device 230 is like the wireless communication device 220 of FIG. 9A, except that the wireless communication device 230 also includes diversity receive features. As illustrated in FIG. 9B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A packaged acoustic wave device comprising:
an interdigital transducer capacitor;
a support pillar over the interdigital transducer capacitor, the support pillar including an insulating material; and
a packaging roof structure coupled to the support pillar.

2. The packaged acoustic wave device of claim 1 wherein the insulating material of the support pillar includes a polyimide.

3. The packaged acoustic wave device of claim 1 wherein the insulating material of the support pillar includes an epoxy-based resin.

4. The packaged acoustic wave device of claim 1 wherein the packaging roof structure includes a dielectric plate.

5. The packaged acoustic wave device of claim 4 wherein the packaging roof structure further includes a conductive layer over the dielectric plate.

6. The packaged acoustic wave device of claim 1 further comprising a seal ring, wherein the packaging roof structure is coupled to the seal ring.

7. The packaged acoustic wave device of claim 6 wherein the seal ring and the packaging roof structure together seal a cavity in which the interdigital transducer capacitor is provided.

8. The packaged acoustic wave device of claim 7 wherein the seal ring surrounds the cavity and the cavity is hermetically sealed.

9. The packaged acoustic wave device of claim 1 wherein the interdigital transducer capacitor includes a piezoelectric layer and an interdigital transducer electrode positioned between at least a portion of the piezoelectric layer and the support pillar.

10. The packaged acoustic wave device of claim 9 wherein the interdigital transducer capacitor further includes a support structure including a support substrate, the piezoelectric layer is positioned over the support structure.

11. The packaged acoustic wave device of claim 10 wherein the support structure further includes an intermediate structure between the support substrate and the piezoelectric layer.

12. The packaged acoustic wave device of claim 11 wherein the intermediate structure includes a functional layer and a trap-rich layer.

13. A packaged filter comprising:
a multi-layer piezoelectric substrate including a support substrate and a piezoelectric layer over the support substrate, the multi-layer piezoelectric substrate having a first region and a second region;
an interdigital transducer capacitor in the first region;
an acoustic wave device in the second region;
a support pillar over the interdigital transducer capacitor, the support pillar including an insulating material; and
a packaging roof structure coupled to the multi-layer piezoelectric substrate via a seal ring and the support pillar.

14. The packaged filter of claim 13 wherein the insulating material of the support pillar includes a polyimide or an epoxy-based resin.

15. The packaged filter of claim 13 wherein the packaging roof structure includes a dielectric plate.

16. The packaged filter of claim 13 wherein multi-layer piezoelectric substrate further includes an intermediate structure between the support substrate and the piezoelectric layer.

17. A packaged interdigital transducer capacitor comprising:
a piezoelectric layer;
a support pillar including an insulating material;
an interdigital transducer electrode between the piezoelectric layer and the support pillar; and
a packaging roof structure coupled to the support pillar.

18. The packaged interdigital transducer capacitor of claim 17 wherein the insulating material of the support pillar includes a polyimide or an epoxy-based resin.

19. The packaged interdigital transducer capacitor of claim 17 further comprising a support structure including a support substrate, the piezoelectric layer is positioned over the support structure.

20. The packaged interdigital transducer capacitor of claim 19 wherein the support structure further includes an intermediate structure between the support substrate and the piezoelectric layer, the intermediate structure includes a functional layer and a trap-rich layer.
